(19) United States
(12) Patent Application Publication
(10) Pub. No.: US 2024/0381007 A1
(43) Pub. Date: Nov. 14, 2024

(54) SOLID-STATE IMAGING APPARATUS AND ELECTRONIC APPARATUS

(71) Applicant: SONY SEMICONDUCTOR SOLUTIONS CORPORATION, KANAGAWA (JP)

(72) Inventor: SATOKO IIDA, KANAGAWA (JP)

(21) Appl. No.: 18/557,298

(22) PCT Filed: Feb. 4, 2022
(86) PCT No.: PCT/JP2022/004383

§ 371 Date: Oct. 26, 2023

(30) Foreign Application Priority Data
May 17, 2021 (JP) 2021-083279

(51) Int. Cl. H04N 25/79; H04N 25/771

(52) U.S. Cl. CPC H04N 25/79; H04N 25/771

(57) ABSTRACT

The present technology relates to a solid-state imaging apparatus and an electronic apparatus that can obtain an image of higher quality. A solid-state imaging apparatus includes a pixel array unit including multiple unit pixels, the unit pixels each including a photoelectric conversion portion, an FD portion configured to retain a charge transferred from the photoelectric conversion portion, and multiple pixel transistors for driving the unit pixel, the photoelectric conversion portion, the FD portion, and a corresponding one of the multiple pixel transistors that is directly connected to the FD portion being provided in the same substrate, and at least one of the multiple pixel transistors that is not directly connected to the FD portion being provided in another substrate different from the substrate. The present technology can be applied to a CMOS image sensor.

### TECHNICAL FIELD

The present technology relates to a solid-state imaging apparatus and an electronic apparatus, and particularly to a solid-state imaging apparatus and an electronic apparatus that can obtain an image of higher quality.

### BACKGROUND ART

Conventionally, in a solid-state imaging apparatus, a configuration is known in which a photoelectric conversion portion and a peripheral circuit unit or a part of a pixel circuit are separately formed on different substrates and are electrically connected to each other (see PTL 1, for example).

PTL 1 proposes a preferable well separation structure in the configuration in which the photoelectric conversion portion and the peripheral circuit unit or a part of the pixel circuit are separately formed on different substrates and are electrically connected to each other. Specifically, PTL 1 discloses one related to the configuration of an amplifier transistor.

In general, the well of an amplifier transistor in a solid-state imaging apparatus in which a substrate is not divided within a single pixel is set at the same ground potential (GND potential) as the well of a photoelectric conversion portion. In addition, it is commonly known that, in such a configuration, the gain (voltage gain) of the amplifier transistor is approximately 0.9.

PTL 1 proposes a structure in which the voltage gain is made to be 1.0 by disposing the amplifier transistor in a substrate different from a substrate where the photoelectric conversion portion is disposed, connecting a source and a back gate of the amplifier transistor to each other, and thereby making the amplifier transistor a self-biased type.

The technology described in PTL 1 forms the amplifier transistor in the substrate different from the substrate where the photoelectric conversion portion is provided and can thereby make the amplifier transistor a self-biased type without reducing the area of the photoelectric conversion portion. Thus, the voltage gain of the amplifier transistor can be set at 1.0, and a charge conversion coefficient can be increased.

### CITATION LIST

### Patent Literature

### [PTL 1]

Japanese Patent Laid-open No. 2012-15400

### SUMMARY

### Technical Problems

However, in order to establish connection to the different substrate to make the amplifier transistor a self-biased type as described above, an FD (Floating Diffusion) portion needs to be disposed in a boundary part between the substrate provided with the photoelectric conversion portion and the substrate provided with the amplifier transistor. In this case, a part of the FD portion is disposed in the same substrate as the amplifier transistor.

When the region of the FD portion is provided in both the upper and lower substrates for such connection to the different substrate, an FD capacitance is increased twofold or more. Then, even when the voltage gain of the amplifier transistor can be changed from 0.9 to 1.0, because the FD capacitance is increased twofold or more, an efficiency of conversion of a charge obtained by photoelectric conversion into a voltage signal is decreased to approximately ½.

While low noise for a high SN (Signal to Noise ratio) is desired for low-illuminance image quality, an increase in the FD capacitance decreases the conversion efficiency, and thus a gain correction for a signal in a subsequent stage becomes necessary. Such a gain correction amplifies noise in each stage and becomes a factor in image quality degradation.

The present technology has been made in view of such circumstances and is intended to make it possible to obtain an image of higher quality.

### Solution to Problems

A solid-state imaging apparatus according to a first aspect of the present technology includes a pixel array unit including multiple unit pixels, the unit pixels each including a photoelectric conversion portion, an FD portion configured to retain a charge transferred from the photoelectric conversion portion, and multiple pixel transistors for driving the unit pixel, the photoelectric conversion portion, the FD portion, and a corresponding one of the multiple pixel transistors that is directly connected to the FD portion being provided in the same substrate, and at least one of the multiple pixel transistors that is not directly connected to the FD portion being provided in another substrate different from the substrate.

In the first aspect of the present technology, the multiple unit pixels are provided in the pixel array unit, and the unit pixels are each provided with the photoelectric conversion portion, the FD portion configured to retain the charge transferred from the photoelectric conversion portion, and the multiple pixel transistors for driving the unit pixel. In addition, the photoelectric conversion portion, the FD portion, and a corresponding one of the multiple pixel transistors that is directly connected to the FD portion being provided in the same substrate, and at least one of the multiple pixel transistors that is not directly connected to the FD portion is provided in another substrate different from the substrate.

An electronic apparatus according to a second aspect of the present technology is an electronic apparatus including the solid-state imaging apparatus according to the first aspect of the present technology.

### BRIEF DESCRIPTION OF DRAWINGS

FIG. 1 is a diagram illustrating an example of a configuration of a CMOS image sensor.

FIG. 2 is a diagram of assistance in explaining a semiconductor substrate in which a pixel array unit is formed.

FIG. 3 is a diagram illustrating an example of a circuit configuration of a unit pixel.

FIG. 4 is a top view of the unit pixel.

FIG. 5 is a sectional view of the unit pixel.

FIG. 6 is a top view of the unit pixel.

FIG. 7 is a sectional view of the unit pixel.

FIG. 8 is a top view of the unit pixel.

FIG. 9 is a sectional view of the unit pixel.

FIG. 10 is a diagram illustrating an example of a circuit configuration of the unit pixel.

FIG. 11 is a top view of the unit pixel.

FIG. 12 is a sectional view of the unit pixel.

FIG. 13 is a diagram illustrating an example of a circuit configuration of the unit pixel.

FIG. 14 is a top view of the unit pixel.

FIG. 15 is a diagram illustrating an example of a configuration of an imaging apparatus.

FIG. 16 is a diagram of assistance in explaining examples of usage of the CMOS image sensor.

FIG. 17 is a block diagram depicting an example of schematic configuration of a vehicle control system.

FIG. 18 is a diagram of assistance in explaining an example of installation positions of an outside-vehicle information detecting section and an imaging section.

### DESCRIPTION OF EMBODIMENTS

Embodiments to which the present technology is applied will hereinafter be described with reference to the drawings.

### First Embodiment

### <Example of Configuration of CMOS Image Sensor>

The present technology makes it possible to obtain a high SN characteristic by arranging a photoelectric conversion portion, an FD portion for retaining a charge transferred from the photoelectric conversion portion, and pixel transistors directly connected to the FD portion in the same substrate and arranging other pixel transistors forming a part in a different substrate. An image of higher quality can be thereby obtained.

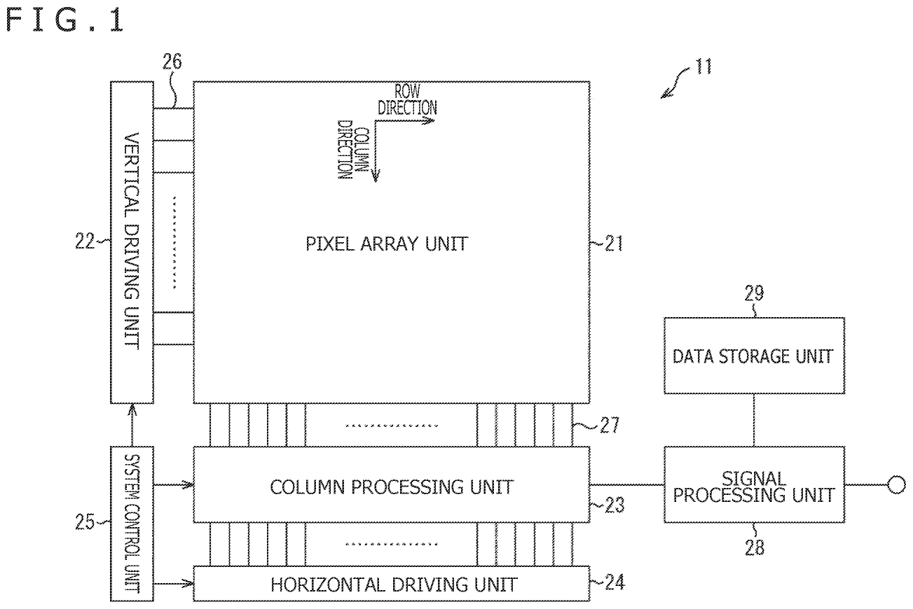

FIG. 1 is a diagram illustrating an example of a configuration of a CMOS (Complementary Metal Oxide Semiconductor) image sensor as a solid-state imaging apparatus to which the present technology is applied.

A CMOS image sensor 11 is, for example, a solid-state imaging apparatus (solid-state imaging element) of a back-illuminated type. The CMOS image sensor 11 has a configuration including a pixel array unit 21 formed on a semiconductor substrate (chip) not illustrated and a peripheral circuit unit integrated on the same semiconductor substrate as the pixel array unit 21.

The peripheral circuit unit, for example, includes a vertical driving unit 22, a column processing unit 23, a horizontal driving unit 24, and a system control unit 25.

The CMOS image sensor 11 further includes a signal processing unit 28 and a data storage unit 29. The signal processing unit 28 and the data storage unit 29 may be disposed on the semiconductor substrate constituting the CMOS image sensor 11 or may be disposed on a substrate different from the semiconductor substrate constituting the CMOS image sensor 11.

The pixel array unit 21 has a configuration in which multiple unit pixels (which may hereinafter be described simply as pixels) including a photoelectric conversion portion that generates and accumulates a charge corresponding to an amount of light received is two-dimensionally arranged in a row direction and a column direction, that is, in a form of a matrix.

Here, the row direction is an arrangement direction of pixels of pixel rows (horizontal direction), that is, a horizontal direction in the figure, and the column direction is an arrangement direction of pixels of pixel columns (vertical direction), that is, a vertical direction in the figure.

For the pixel arrangement in the matrix form in the pixel array unit 21, pixel driving lines 26 are routed for the respective pixel rows along the row direction, and vertical signal lines 27 are routed for the respective pixel columns along the column direction. The pixel driving lines 26 are signal lines for supplying driving signals (control signals) for driving pixels, such as driving at a time of reading signals from the pixels. One ends of the pixel driving lines 26 are connected to output terminals corresponding to the respective rows of the vertical driving unit 22.

Incidentally, here, for easy viewing of the figure, one pixel driving line 26 is depicted for one pixel row. In reality, however, multiple pixel driving lines 26 are routed for one pixel row.

The vertical driving unit 22 includes, for example, a shift register, an address decoder, or the like. The vertical driving unit 22 drives all of the pixels of the pixel array unit 21 simultaneously or drives the pixels in row units or the like.

The vertical driving unit 22, for example, has a configuration including two scanning systems, that is, a readout scanning system and a sweeping scanning system.

The readout scanning system sequentially selects and scans the unit pixels of the pixel array unit 21 in row units in order to read signals from the unit pixels. The signals read from the unit pixels are analog signals.

The sweeping scanning system performs sweeping scanning in predetermined timing on a readout row in which the readout scanning system performs readout scanning. The sweeping scanning of the sweeping scanning system sweeps out unnecessary charges from the photoelectric conversion portions of the unit pixels in the readout row. The photoelectric conversion portions are thereby reset.

The signals output from the unit pixels of a pixel row selected and scanned by the vertical driving unit 22 are input to the column processing unit 23 via the vertical signal lines 27 in the respective pixel columns.

The column processing unit 23 performs predetermined signal processing on the signals supplied from the respective pixels of the selected row via the vertical signal lines 27 in the respective pixel columns of the pixel array unit 21, and temporarily retains the pixel signals obtained after the signal processing.

The column processing unit 23, for example, performs, as the signal processing, noise removal processing, CDS (Correlated Double Sampling) processing (correlated double sampling), AD (Analog to Digital) conversion processing, and the like. The CDS processing, for example, removes reset noise and fixed pattern noise unique to the pixels such as threshold value variations in amplifier transistors in the pixels.

The horizontal driving unit 24 includes a shift register, an address decoder, or the like. The horizontal driving unit 24 selects unit circuits corresponding to the pixel columns in the column processing unit 23 in order. The selection scanning of the horizontal driving unit 24 causes the pixel signals resulting from the signal processing by the respective unit circuits in the column processing unit 23 to be output to the signal processing unit 28 in order.

The system control unit 25 includes a timing generator that generates various kinds of timing signals or the like. The system control unit 25 performs driving control of the vertical driving unit 22, the column processing unit 23, the horizontal driving unit 24, and the like on the basis of the generated timing signals.

The signal processing unit 28 at least has an arithmetic processing function. The signal processing unit 28 performs various kinds of signal processing such as arithmetic processing on the pixel signals output from the column processing unit 23. When the signal processing unit 28 performs the signal processing, the data storage unit 29 temporarily stores data necessary for the processing.

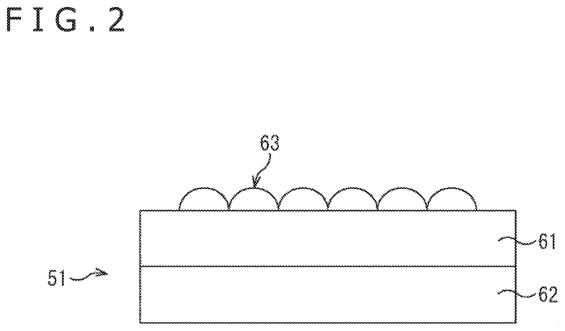

In addition, the pixel array unit 21 is formed in a semiconductor substrate 51, as illustrated in FIG. 2, for example.

In the present example, the semiconductor substrate 51 is formed by joining together a first substrate 61 as a Si substrate and a second substrate 62. Multiple on-chip lenses 63 are also provided on a surface of the first substrate 61 which surface is on an opposite side of the second substrate 62 side. The on-chip lenses 63 condense light incident from an upper side in FIG. 2 and make the light incident on the semiconductor substrate 51.

In addition, though not illustrated, color filters are also formed between the on-chip lens 63 and the first substrate 61.

In the CMOS image sensor 11, the pixel array unit 21, that is, the multiple unit pixels constituting the pixel array unit 21, are formed in such a semiconductor substrate 51.

### <Example of Circuit Configuration of Unit Pixels>

Description will next be made regarding an example of a circuit configuration of a unit pixel provided to the pixel array unit 21.

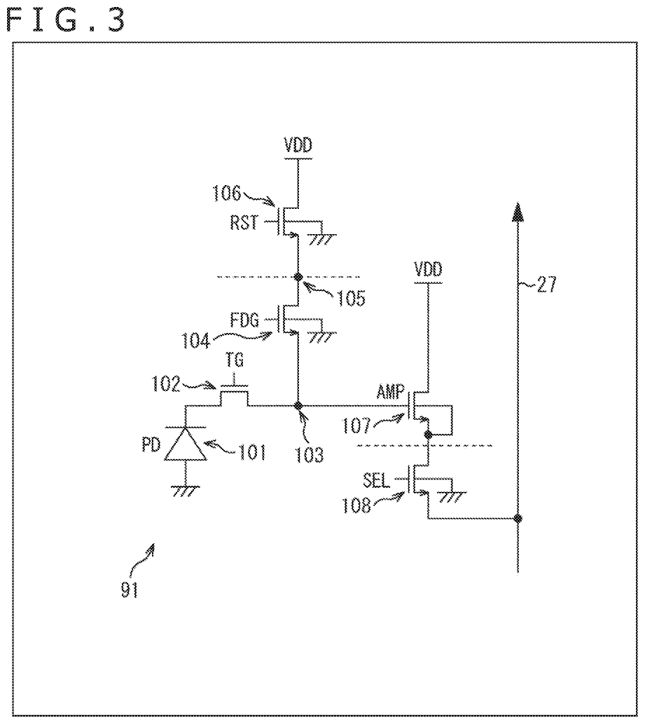

The pixel array unit 21 is provided with multiple unit pixels 91 having a circuit configuration illustrated in FIG. 3, for example. These unit pixels 91 are connected to the vertical signal lines 27.

Each of the unit pixels 91 includes a photoelectric conversion portion 101, a transfer transistor 102, an FD portion 103, a switching transistor 104, an FD portion 105, a reset transistor 106, an amplifier transistor 107, and a selecting transistor 108.

In particular, in the unit pixel 91, provided as a pixel transistor group for driving the unit pixel 91 are the transfer transistor 102, the switching transistor 104, the reset transistor 106, the amplifier transistor 107, and the selecting transistor 108.

The photoelectric conversion portion 101 includes an embedded photodiode (PD (Photodiode)), for example. The photoelectric conversion portion 101 receives light incident from the on-chip lens 63 and performs photoelectric conversion. The photoelectric conversion portion 101 thereby generates a charge (signal) corresponding to an amount of the incident light.

The transfer transistor 102 includes a polysilicon electrode, for example. The transfer transistor 102 is turned on or off according to a signal supplied from the vertical driving unit 22. The transfer transistor 102 transfers the charge (signal) obtained by the photoelectric conversion in the photoelectric conversion portion 101 from the photoelectric conversion portion 101 to the FD portion 103.

The FD portion 103 is a floating diffusion region (floating diffusion). The FD portion 103 functions as a charge retaining portion that retains (stores) the charge transferred from the photoelectric conversion portion 101 via the transfer transistor 102.

In addition, the FD portion 103 is directly connected with the transfer transistor 102, the switching transistor 104, and the amplifier transistor 107.

The switching transistor 104 is a transistor having a source potential (source) in the same part as a part serving as the FD portion 103 of the transfer transistor 102. The switching transistor 104 is turned on or off according to a signal supplied from the vertical driving unit 22, and thereby changes the magnitude of an FD capacitance of the unit pixel 91. That is, the switching transistor 104 is a pixel transistor for connecting the FD portion 103 and the FD portion 105 to each other.

The FD portion 105 is a floating diffusion region provided between the switching transistor 104 and the reset transistor 106.

When the switching transistor 104 is, for example, set in an on state (conduction state) to electrically connect the FD portion 103 and the FD portion 105 to each other, the charge obtained by the photoelectric conversion portion 101 is stored not only in the FD portion 103 but also in the FD portion 105. Hence, in such a case, the FD capacitance of the unit pixel 91 is increased by an amount corresponding to the FD portion 105.

An efficiency of conversion of the charge stored in the FD portion 103 or the like into a voltage signal changes according to the magnitude of the FD capacitance of such a unit pixel 91. The switching transistor 104 can therefore be also said to be a transistor for changing the conversion efficiency.

The reset transistor 106 is connected to a power supply VDD. The reset transistor 106 is turned on or off according to a signal supplied from the vertical driving unit 22.

When the reset transistor 106 and the switching transistor 104 are set in an on state, for example, the charge stored in the FD portion 103 and the FD portion 105 is discharged to the power supply VDD. An input to a gate electrode of the amplifier transistor 107 connected to the FD portion 103 is thereby reset to a predetermined potential.

The amplifier transistor 107 amplifies and outputs the signal (charge) retained in the FD portion 103 or the like after being transferred from the photoelectric conversion portion 101 to the FD portion 103 or the like via the transfer transistor 102.

That is, the amplifier transistor 107 forms a source follower circuit with a constant-current source connected via the vertical signal line 27. The amplifier transistor 107 outputs a voltage signal exhibiting a level corresponding to the charge retained in the FD portion 103 or the FD portion 103 and the FD portion 105 to the column processing unit 23 via the selecting transistor 108 and the vertical signal line 27.

The selecting transistor 108 is provided between a source electrode of the amplifier transistor 107 and the vertical signal line 27. The selecting transistor 108 controls conduction between the amplifier transistor 107 and the vertical signal line 27 by being turned on or off according to a signal supplied from the vertical driving unit 22.

In the unit pixel 91 having the configuration as described above, the photoelectric conversion portion 101, the transfer transistor 102, the FD portion 103, the switching transistor 104, and the amplifier transistor 107 are formed in the first substrate 61.

In addition, the FD portion 105 is provided in a boundary part between the first substrate 61 and the second substrate 62, and the reset transistor 106 and the selecting transistor 108 are provided in the second substrate 62 different from the first substrate 61.

### <Example of Arrangement of Pixel Transistors>

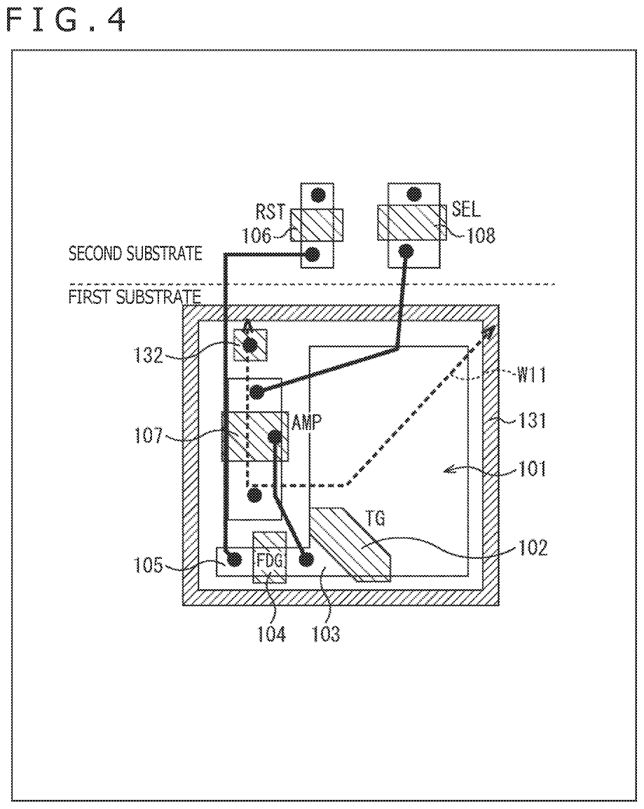

Next, with reference to FIG. 4, description will be made regarding an arrangement of the photoelectric conversion portion 101 and the pixel transistors in the unit pixel 91.

FIG. 4 illustrates a view (top view) of the unit pixel 91 as viewed from a direction perpendicular to the surface of the semiconductor substrate 51.

In the present example, a part of a region forming the unit pixel 91 in a well of the first substrate 61, that is, a boundary part of the unit pixel 91, is surrounded by a through DTI (Deep Trench Isolation) 131 formed by an insulator (insulating film) or the like.

The through DTI 131 functions as an inter-pixel light shielding portion that suppresses incidence of light made externally incident via the on-chip lens 63 on another unit pixel 91 adjacent to the unit pixel 91 within the first substrate 61, that is, suppresses the occurrence of a color mixture (leaking in of light).

The through DTI 131 is, for example, a separating portion of a trench structure obtained by forming a groove penetrating the first substrate 61 and embedding an insulator in the groove.

Incidentally, while description will be made here of an example in which the through DTI 131 is provided as the inter-pixel light shielding portion, the inter-pixel light shielding portion may be anything as long as the inter-pixel light shielding portion is formed by an insulator such as polysilicon, an air gap, or a combination of polysilicon and an air gap.

The photoelectric conversion portion 101, the transfer transistor 102, the FD portion 103, the switching transistor 104, the FD portion 105, and the amplifier transistor 107 are formed within a region surrounded by the through DTI 131 in the first substrate 61.

In addition, within the region surrounded by the through DTI 131 in the first substrate 61, a well contact 132 for connecting the well of the first substrate 61 to a ground (GND) is also provided. A drain electrode of the amplifier transistor 107 is connected to the power supply VDD.

The reset transistor 106 and the selecting transistor 108 among the multiple pixel transistors constituting the unit pixel 91 are provided in the second substrate 62.

Thus, in the unit pixel 91, the photoelectric conversion portion 101, the transfer transistor 102 directly connected to the photoelectric conversion portion 101, and the FD portion 103 that retains the charge obtained by the photoelectric conversion portion 101 are provided in the same first substrate 61.

In addition, of the multiple pixel transistors constituting the unit pixel 91, not only the transfer transistor 102 but also the switching transistor 104 and the amplifier transistor 107 directly connected to the FD portion 103 are provided in the same first substrate 61 as the photoelectric conversion portion 101.

Further, in the unit pixel 91, the FD portion 105 is formed in a connection part (boundary part) between the first substrate 61 and the second substrate 62. That is, a part of the FD portion 105 is provided in the first substrate 61, and a remaining part of the FD portion 105 is provided in the second substrate 62.

Because the FD portion 105 is provided in the connection part between the first substrate 61 and the second substrate 62, the FD capacitance of the FD portion 105 increases. However, the increase in the FD capacitance of the FD portion 105 is unrelated to an increase in the FD capacitance of the FD portion 103 in a case where a charge is retained in only the FD portion 103.

For example, in the unit pixel 91, in a high conversion efficiency mode with a higher conversion efficiency, the high conversion efficiency mode being used for low illuminance, the switching transistor 104 is set in an off (non-conducting) state. That is, the FD portion 103 and the FD portion 105 are set in a state of being electrically disconnected from each other.

Then, the charge obtained by the photoelectric conversion portion 101 is retained only in the FD portion 103, and the signal corresponding to the charge is output from the amplifier transistor 107 to the vertical signal line 27 via the selecting transistor 108.

In contrast, the charge is retained also in the FD portion 105, that is, the FD portion 105 becomes a region of a signal detection target, at a time of a low conversion efficiency mode with a lower conversion efficiency than at a time of the high conversion efficiency mode, the low conversion efficiency mode being used for medium illuminance.

In the low conversion efficiency mode, the switching transistor 104 is set in an on (conducting) state. That is, the FD portion 103 and the FD portion 105 are set in a state of being electrically connected to each other.

Then, the charge obtained by the photoelectric conversion portion 101 is retained in the FD portion 103 and the FD portion 105, and the signal corresponding to the charge is output from the amplifier transistor 107 to the vertical signal line 27 via the selecting transistor 108.

In a case where photographing is performed while switching is performed between the low conversion efficiency mode and the high conversion efficiency mode, minimization of the FD capacitance, that is, suppression of an increase in the FD capacitance, is necessary at the time of the high conversion efficiency mode used for low illuminance.

In the high conversion efficiency mode, when an increase in the FD capacitance of the FD portion 103 can be suppressed, a decrease in conversion efficiency can be suppressed, and the SN characteristic of the signal (pixel signal) read from the unit pixel 91 (FD portion 103) can be improved. Then, an image of high quality with little noise can be obtained, and a gain correction in a stage subsequent to the unit pixel 91 does not need to be performed.

Accordingly, in the unit pixel 91, the FD portion 103 used in the high conversion efficiency mode is disposed in the first substrate 61 provided with the photoelectric conversion portion 101 rather than in the connection part between the first substrate 61 and the second substrate 62.

In addition, the switching transistor 104 and the amplifier transistor 107 directly connected to the FD portion 103 are also disposed in the first substrate 61 as with the FD portion 103. Further, the FD portion 105 unrelated to an increase in the FD capacitance in the high conversion efficiency mode is provided in the connection part between the first substrate 61 and the second substrate 62.

This can minimize the FD capacitance of the FD portion 103 (suppress an increase in the FD capacitance), thereby improve the SN characteristic, and consequently obtain an image of higher quality.

Furthermore, in the unit pixel 91, at least one of the pixel transistors unrelated to the minimization of the FD capacitance of the FD portion 103, that is, not directly connected to the FD portion 103, is provided in the other substrate different from the first substrate 61. In the present example, the reset transistor 106 and the selecting transistor 108 not directly connected to the FD portion 103 are provided in the second substrate 62 different from the first substrate 61.

Thus, in the first substrate 61, the area of the photoelectric conversion portion 101 can be made larger by an amount corresponding to the reset transistor 106 and the selecting transistor 108 while the FD capacitance of the FD portion 103 is minimized. As a result, it is possible to obtain more charge by the photoelectric conversion portion 101, that is, improve sensitivity, and consequently obtain an image of an even higher quality.

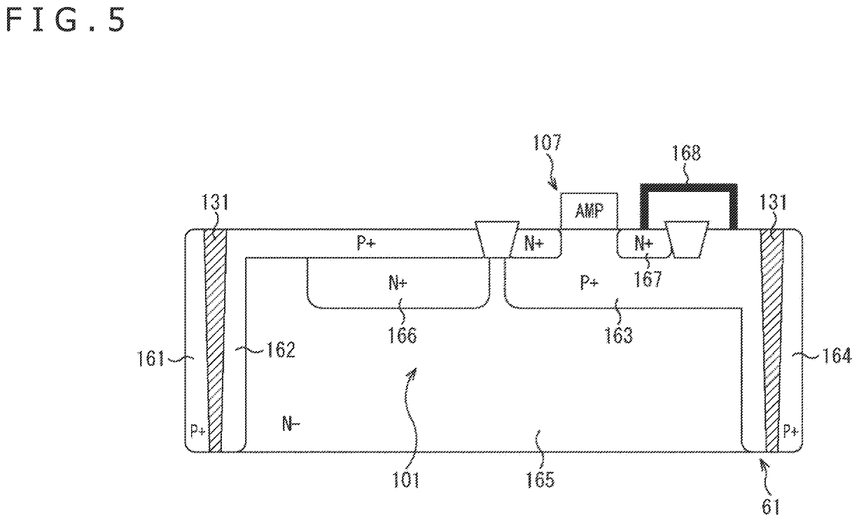

In addition, a section of a part indicated by an arrow W11 in the first substrate 61 is as illustrated in FIG. 5, for example.

In the present example, a surface on a lower side of the first substrate 61 in the figure is a surface on a light incidence side, that is, a surface on a side where the on-chip lenses 63, is formed.

In addition, in the first substrate 61, P+ regions 161 to 164 as P-type semiconductor regions are well (P-well) regions formed in the first substrate 61.

In particular, in this case, the P+ region 161 and the P+ region 162 are electrically separated from each other by the through DTI 131 penetrating the first substrate 61, and similarly the P+ region 163 and the P+ region 164 are electrically separated from each other by the through DTI 131.

In addition, an N− region 165 and an N+ region 166 as N− type semiconductor regions are formed in a part surrounded by the through DTI 131 in the first substrate 61, or more specifically a part surrounded by the P+ region 162 and the P+ region 163. A region including the N− region 165 and the N+ region 166 functions as the photoelectric conversion portion 101.

Further, an N+ region 167 serving as the source electrode of the amplifier transistor 107 is formed within the P+ region 163, and the N+ region 167 and the P+ region 163 are electrically connected to each other by wiring 168.

In other words, the P+ region 163 directly under the gate electrode of the amplifier transistor 107, that is, a back gate, and the source electrode of the amplifier transistor 107 are electrically connected to each other by the wiring 168. Hence, the amplifier transistor 107 is a self-biased transistor.

Thus, a voltage gain of the amplifier transistor 107 can be set at 1.0, and a charge conversion coefficient can be increased. That is, the efficiency of conversion of the charge into a voltage signal in the unit pixel 91 can be made higher, and further the SN characteristic can be improved.

In addition, an insulator is provided between a part of the P+ region 162 which part is in the vicinity of the N+ region 166 and the P+ region 163. This insulator electrically separates the P+ region 162 and the P+ region 163 from each other.

### Second Embodiment

### <Another Example of Configuration of Unit Pixel>

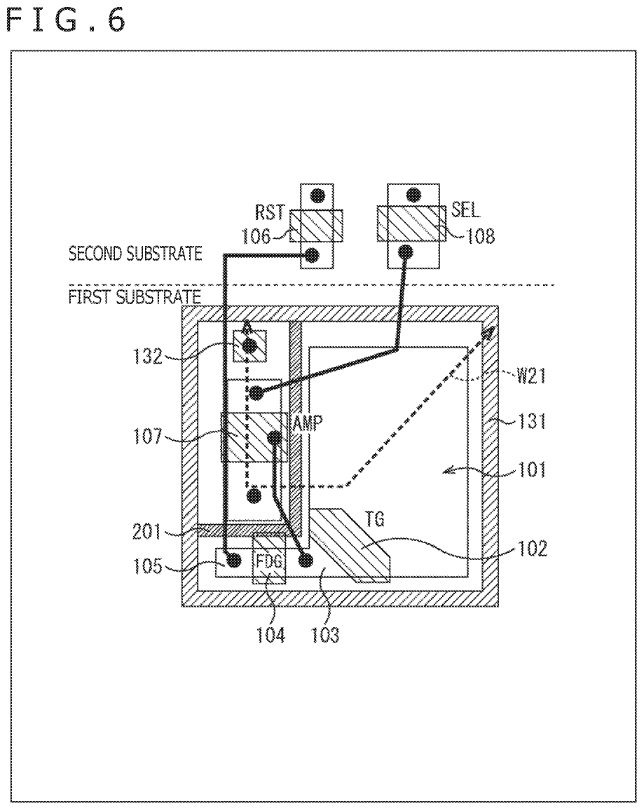

In addition, in a case where the unit pixel 91 has the circuit configuration illustrated in FIG. 3, a well in which the photoelectric conversion portion 101 is formed and a well in which the amplifier transistor 107 is formed may be electrically separated from each other, as illustrated in FIG. 6, for example. Incidentally, in FIG. 6, parts corresponding to those in the case of FIG. 4 are identified by the same reference signs, and description thereof will be omitted as appropriate.

FIG. 6 illustrates a view (top view) of the unit pixel 91 as viewed from a direction perpendicular to the surface of the semiconductor substrate 51.

A configuration of the unit pixel 91 illustrated in FIG. 6 and an arrangement of each element and the like are different from the configuration and the arrangement illustrated in FIG. 4 in that a front DTI 201 is newly provided but are otherwise the same as in the case of FIG. 4.

In the example of FIG. 6, the front DTI 201 including an insulator is formed between the photoelectric conversion portion 101 and the amplifier transistor 107 in the first substrate 61.

Thus, the through DTI 131 and the front DTI 201 function as a separating portion, and a part in which the photoelectric conversion portion 101 is formed and a part in which the amplifier transistor 107 is formed in the well of the first substrate 61 are electrically separated from each other by the separating portion. That is, a boundary between the well of the photoelectric conversion portion 101 and the well of the amplifier transistor 107 are insulated by the separating portion.

Incidentally, in the following, description will be made regarding an example in which the front DTI 201 is provided as the separating portion formed between the photoelectric conversion portion 101 and the amplifier transistor 107, or more specifically as a part of the separating portion. However, the separating portion (part of the separating portion) may be anything as long as the separating portion is formed by an insulator such as an insulating film, an air gap, or a combination of an insulating film and an air gap.

In addition, in order to connect each of the well of the photoelectric conversion portion 101 and the well of the amplifier transistor 107 which wells are insulated from each other to the ground (GND), a well contact for connecting the well of the photoelectric conversion portion 101 to the ground is also formed in addition to the well contact 132.

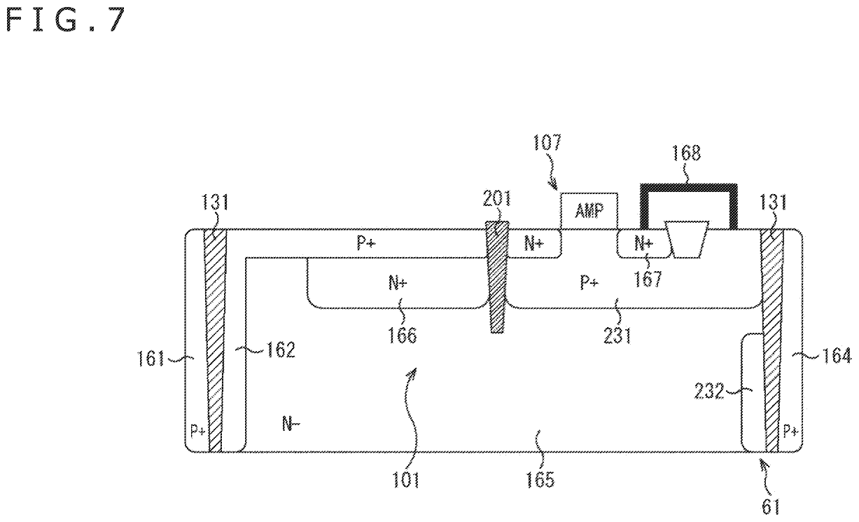

Further, a section of a part indicated by an arrow W21 in the first substrate 61 is as illustrated in FIG. 7, for example.

In the present example, a surface on a lower side of the first substrate 61 in the figure is a surface on a light incidence side, that is, a surface on a side where the on-chip lenses 63, is formed.

In addition, in the first substrate 61, a P+ region 161, a P+ region 162, a P+ region 164, a P+ region 231, and a P+ region 232 as P-type semiconductor regions are well (P-well) regions formed in the first substrate 61.

In particular, the N− region 165 and the N+ region 166 constituting the photoelectric conversion portion 101 are formed in the part of the P+ region 162, and the amplifier transistor 107 is formed in the part of the P+ region 231. In addition, the N+ region 167 and the P+ region 231 are electrically connected to each other by the wiring 168. Thus, the amplifier transistor 107 is a self-biased transistor.

The front DTI 201 is a separating portion of a trench structure obtained by forming a groove not penetrating the first substrate 61, the groove extending from a surface of the first substrate 61 which surface is on the second substrate 62 side to a midpoint of the first substrate 61, and embedding an insulator in the groove.

In the unit pixel 91, at a part where the photoelectric conversion portion 101 (N+ region 166) and the amplifier transistor 107 are adjacent to each other, that is, a part between the photoelectric conversion portion 101 and the amplifier transistor 107, the front DTI 201 provided to the part is formed to reach a position deeper than the P+ region 162 and the P+ region 231. That is, the front DTI 201 is longer than the P+ region 162 and the P+ region 231 in a depth direction (direction perpendicular to the surface of the first substrate 61).

In the present example, in a part in contact with the front DTI 201, the front DTI 201 is formed to reach a position below the P+ region 162 and the P+ region 231 in the figure, that is, a position deeper than the P+ region 162 and the P+ region 231. Hence, in the part between the photoelectric conversion portion 101 and the amplifier transistor 107, the P+ region 162 and the P+ region 231 are electrically separated (insulated) from each other by the front DTI 201.

In addition, as also illustrated in FIG. 6, the P+ region 162 as the well of the photoelectric conversion portion 101 is surrounded by the front DTI 201 and the through DTI 131, and the P+ region 231 as the well of the amplifier transistor 107 is also surrounded by the front DTI 201 and the through DTI 131.

Hence, the P+ region 162 and the P+ region 231 are electrically separated from each other (there is no conduction therebetween) by the front DTI 201 and the through DTI 131.

When the well of the photoelectric conversion portion 101 and the well of the amplifier transistor 107 are electrically separated from each other as described above, it is not necessary to perform well separation by securing a large distance between the photoelectric conversion portion 101 and the amplifier transistor 107. That is, the photoelectric conversion portion 101 and the amplifier transistor 107 can be arranged in closer proximity to each other than in the example of FIG. 5.

Hence, the area of the photoelectric conversion portion 101 in the unit pixel 91 can be made larger. In other words, a reduction in the area of the photoelectric conversion portion 101 can be minimized. Thus, the sensitivity (conversion efficiency) of the unit pixel 91, that is, the SN characteristic can be improved, so that an image of an even higher quality can be obtained.

In the second embodiment, as in the first embodiment, the FD capacitance can be minimized, and the voltage gain can be set at 1.0 with the amplifier transistor 107 formed as a self-biased type. Consequently, an image of an even higher quality than in the case of the first embodiment can be obtained.

### Third Embodiment

### <Another Example of Configuration of Unit Pixel>

It is to be noted that while the inter-pixel light shielding portion surrounding the region of the unit pixel 91 is implemented by the through DTI 131 in the example illustrated in FIG. 6, a front DTI may be provided in place of the through DTI 131.

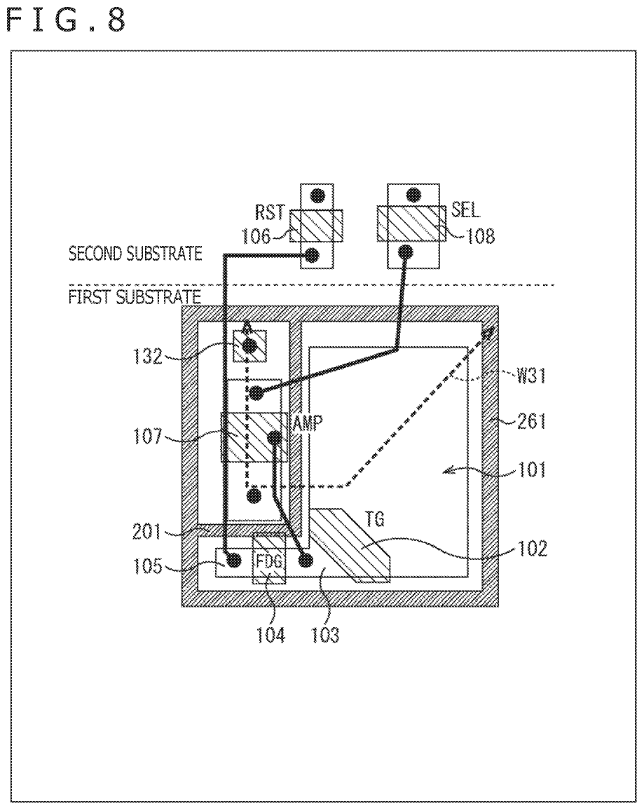

In such a case, a top view of the unit pixel 91 having the circuit configuration illustrated in FIG. 3 as viewed from a direction perpendicular to the surface of the semiconductor substrate 51 is as illustrated in FIG. 8, for example. Incidentally, in FIG. 8, parts corresponding to those in the case of FIG. 6 are identified by the same reference signs, and description thereof will be omitted as appropriate.

A configuration of the unit pixel 91 illustrated in FIG. 8 and an arrangement of each element and the like are different from the configuration and the arrangement illustrated in FIG. 6 in that a front DTI 261 is provided in place of the through DTI 131 but are otherwise the same as in the case of FIG. 6.

In FIG. 8, a part of a region forming the unit pixel 91 in the well of the first substrate 61, that is, a boundary part of the unit pixel 91, is surrounded by the front DTI 261 formed by an insulator (insulating film) or the like.

In addition, the front DTI 201 is formed between the photoelectric conversion portion 101 and the amplifier transistor 107 in the first substrate 61. Then, the part of the photoelectric conversion portion 101 and the part of the amplifier transistor 107 are each surrounded by the front DTI 261 and the front DTI 201.

Thus, the front DTI 261 and the front DTI 201 function as a separating portion, and the part in which the photoelectric conversion portion 101 is formed and the part in which the amplifier transistor 107 is formed in the well of the first substrate 61 are electrically separated from each other by the separating portion.

Further, in order to connect each of the well of the photoelectric conversion portion 101 and the well of the amplifier transistor 107 which wells are separated from each other to the ground (GND), a well contact for connecting the well of the photoelectric conversion portion 101 to the ground is also formed as in the case of FIG. 6.

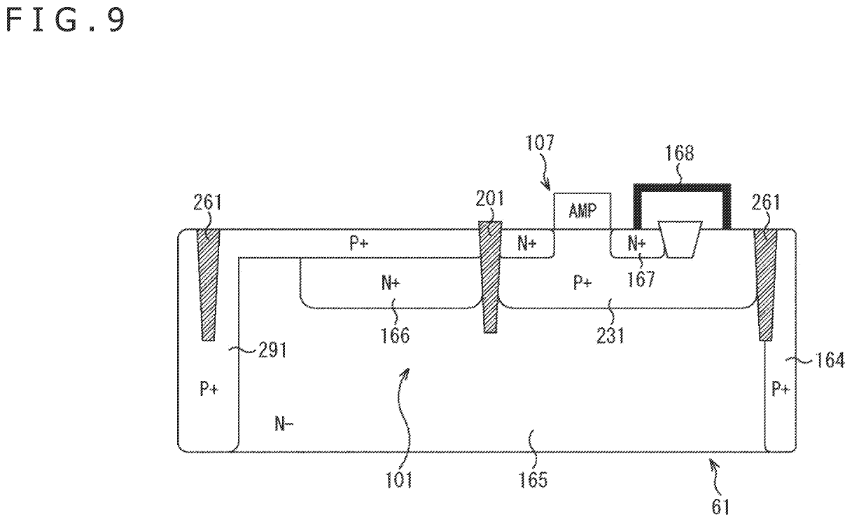

Further, a section of a part indicated by an arrow W31 in the first substrate 61 is as illustrated in FIG. 9, for example.

In the present example, a surface on a lower side of the first substrate 61 in the figure is a surface on a light incidence side, that is, a surface on a side where the on-chip lenses 63, is formed.

In addition, in the first substrate 61, a P+ region 291, a P+ region 164, and a P+ region 231 as P-type semiconductor regions are well (P-well) regions formed in the first substrate 61.

In particular, the N− region 165 and the N+ region 166 constituting the photoelectric conversion portion 101 are formed in the part of the P+ region 291, and the amplifier transistor 107 is formed in the part of the P+ region 231. In addition, the N+ region 167 and the P+ region 231 are electrically connected to each other by the wiring 168. Thus, the amplifier transistor 107 is a self-biased transistor.

The front DTI 261 is a separating portion of a trench structure obtained by forming a groove not penetrating the first substrate 61, the groove extending from a surface of the first substrate 61 which surface is on the second substrate 62 side to a midpoint of the first substrate 61, and embedding an insulator in the groove.

The front DTI 261 functions also as an inter-pixel light shielding portion that suppresses the occurrence of a color mixture.

The front DTI 261 is not formed to reach a deep position as compared with the through DTI 131. Therefore, the color mixture occurs in response to oblique incidence more easily than in the case where the through DTI 131 is provided. However, the color mixture can be reduced sufficiently by a light condensing design of the on-chip lenses 63 or the like.

The front DTI 261 and the front DTI 201 are both a front DTI and have the same depth and the same configuration. That is, a configuration such that the through DTI and the front DTI are formed separately as in the example of FIG. 7 is not adopted. Hence, in the CMOS image sensor 11, the front DTI 261 and the front DTI 201 can be formed in the same process, so that the number of processes during manufacture can be reduced.

In addition, also in the present example, as in the example illustrated in FIG. 7, the P+ region 291 as the well of the photoelectric conversion portion 101 and the P+ region 231 as the well of the amplifier transistor 107 are electrically separated (insulated) from each other by the front DTI 201 and the front DTI 261.

Hence, as in the case of FIG. 7, the photoelectric conversion portion 101 and the amplifier transistor 107 can be arranged in closer proximity to each other than in the example of FIG. 5. It is thereby possible to make the area of the photoelectric conversion portion 101 larger, thus improve the sensitivity (conversion efficiency) of the unit pixel 91, that is, the SN characteristic, and consequently obtain an image of high quality.

Further, as in the first embodiment, the FD capacitance can be minimized, and the voltage gain can be set at 1.0 with the amplifier transistor 107 formed as a self-biased type. Consequently, an image of an even higher quality than in the case of the first embodiment can be obtained.

### Fourth Embodiment

### <Example of Circuit Configuration of Unit Pixel>

Now, while in the above, description has been made regarding an example in which one photoelectric conversion portion 101 is provided within the unit pixel 91, two or more photoelectric conversion portions of different sizes may be provided within the unit pixel.

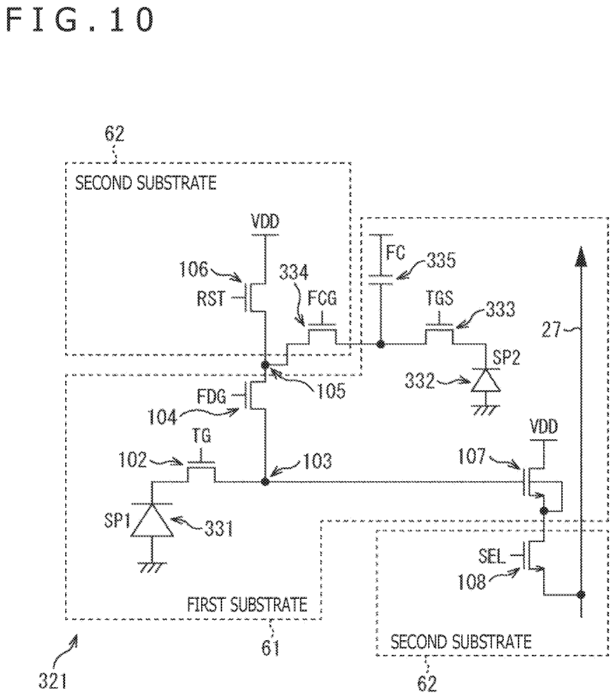

In such a case, a circuit configuration of the unit pixel provided in the pixel array unit 21 is as illustrated in FIG. 10, for example. Incidentally, in FIG. 10, parts corresponding to those in the case of FIG. 3 are identified by the same reference signs, and description thereof will be omitted as appropriate.

In an example illustrated in FIG. 10, a unit pixel 321 includes a photoelectric conversion portion 331, a transfer transistor 102, an FD portion 103, a switching transistor 104, an FD portion 105, a reset transistor 106, a photoelectric conversion portion 332, a transfer transistor 333, a switching transistor 334, a charge storage capacitance 335, an amplifier transistor 107, and a selecting transistor 108.

In particular, in the unit pixel 321, provided as a pixel transistor group are the transfer transistor 102, the switching transistor 104, the reset transistor 106, the transfer transistor 333, the switching transistor 334, the amplifier transistor 107, and the selecting transistor 108.

In addition, the unit pixel 321 is provided with two photoelectric conversion portions, that is, the photoelectric conversion portion 331 and the photoelectric conversion portion 332, which have sizes different from each other, that is, areas (areas of light receiving surfaces) different from each other.

The photoelectric conversion portion 331 includes, for example, an embedded PD, and functions as a large-area pixel provided within the unit pixel 321 and having a larger area.

The photoelectric conversion portion 331 generates a charge by receiving externally incident light and performing photoelectric conversion and transfers the obtained charge to the FD portion 103 via the transfer transistor 102.

The photoelectric conversion portion 332 includes, for example, an embedded PD, and functions as a small-area pixel provided within the unit pixel 321 and having an area smaller than that of the photoelectric conversion portion 331. The photoelectric conversion portion 332 is provided to obtain a signal for high illuminance higher than low illuminance and medium illuminance for which only the photoelectric conversion portion 331 is used.

The photoelectric conversion portion 332 generates a charge by receiving externally incident light and performing photoelectric conversion and transfers the obtained charge to the charge storage capacitance 335 via the transfer transistor 333.

The transfer transistor 333 is turned on or off according to a signal supplied from the vertical driving unit 22. The transfer transistor 333 transfers the charge (signal) obtained by the photoelectric conversion in the photoelectric conversion portion 332 from the photoelectric conversion portion 332 to the charge storage capacitance 335.

In addition, in the unit pixel 321, the FD portion 105 is connected with not only the switching transistor 104 and the reset transistor 106 but also the switching transistor 334.

Further, the charge storage capacitance 335 that functions as an intra-pixel capacitance is provided between the switching transistor 334 and the transfer transistor 333. The charge storage capacitance 335 retains the charge transferred from the photoelectric conversion portion 332 via the transfer transistor 333.

The switching transistor 334 is a pixel transistor for switching between the readout of the signal obtained by the large-area pixel (photoelectric conversion portion 331) and the readout of the signal obtained by the small-area pixel (photoelectric conversion portion 332).

For example, at a time of the readout of the signal obtained by the large-area pixel, the switching transistor 104 is set in an on or off state, and the switching transistor 334 is set in an off state.

More specifically, as in the example of FIG. 3, for example, in the high conversion efficiency mode, a signal is output from the amplifier transistor 107 in a state in which the switching transistor 104 is off and the charge obtained by the photoelectric conversion portion 331 is retained in only the FD portion 103.

In addition, in the low conversion efficiency mode, as in the example of FIG. 3, a signal is output from the amplifier transistor 107 in a state in which the switching transistor 104 is on and the charge obtained by the photoelectric conversion portion 331 is retained in the FD portion 103 and the FD portion 105.

At a time of the readout of the signal obtained by the small-area pixel, on the other hand, the switching transistor 104 and the switching transistor 334 are set in an on state. Hence, a signal is output from the amplifier transistor 107 in a state in which the charge obtained by the photoelectric conversion portion 332 is retained in the FD portion 103, the FD portion 105, and the charge storage capacitance 335, for example.

In such a unit pixel 321, the photoelectric conversion portion 331, the transfer transistor 102, the FD portion 103, the switching transistor 104, the photoelectric conversion portion 332, the transfer transistor 333, the charge storage capacitance 335, and the amplifier transistor 107 are provided in the first substrate 61.

In addition, although the FD portion 105 is provided at a connection part between the first substrate 61 and the second substrate 62, the FD portion 105 is a region that becomes a signal detection target at a time of the low conversion efficiency mode, and in the high conversion efficiency mode, the FD portion 105 is unrelated, that is, the FD portion 105 is a region that does not become a detection target.

The second substrate 62 is provided with the reset transistor 106, the switching transistor 334, and the selecting transistor 108.

In the unit pixel 321, as in the example of the unit pixel 91, the photoelectric conversion portion 331 and the FD portion 103 used in the high conversion efficiency mode as well as the transfer transistor 102, the switching transistor 104, and the amplifier transistor 107 directly connected to the FD portion 103 are provided in the first substrate 61.

Hence, also in the unit pixel 321, it is possible to minimize the FD capacitance of the FD portion 103 (suppress an increase in the FD capacitance), thereby improve the SN characteristic, and consequently obtain an image of higher quality.

In addition, in the unit pixel 321, as in the case of the unit pixel 91, the reset transistor 106, the switching transistor 334, and the selecting transistor 108, which are unrelated to the minimization of the FD capacitance of the FD portion 103, are provided in the second substrate 62.

It is thus possible to improve sensitivity by making the areas of the photoelectric conversion portion 331 and the photoelectric conversion portion 332 larger while minimizing the FD capacitance of the FD portion 103. Consequently, an image of an even higher quality can be obtained.

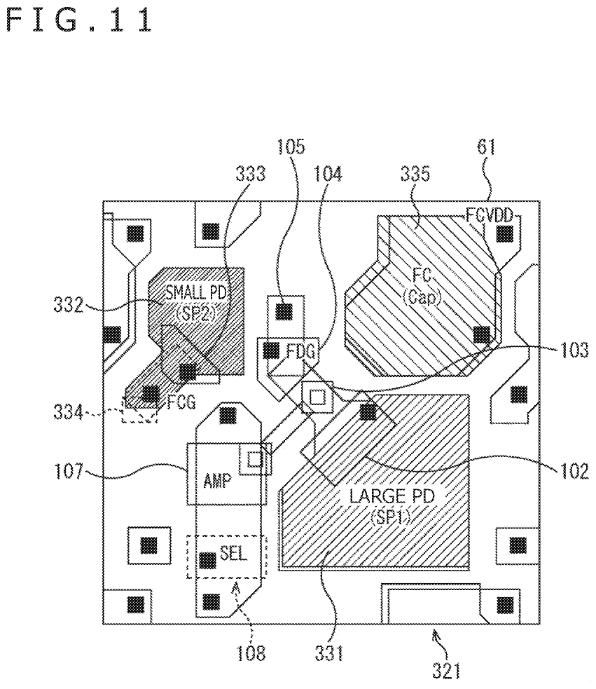

FIG. 11 illustrates a view (top view) of the part of the first substrate 61 of the unit pixel 321 as viewed from a direction perpendicular to the surface of the first substrate 61.

In the present example, arranged on the first substrate 61 are the photoelectric conversion portion 331, the transfer transistor 102, the FD portion 103, the switching transistor 104, the photoelectric conversion portion 332, the transfer transistor 333, the charge storage capacitance 335, and the amplifier transistor 107.

In particular, it is understood that, as viewed from the direction perpendicular to the surface of the first substrate 61, the area of the photoelectric conversion portion 331 is larger than the area of the photoelectric conversion portion 332.

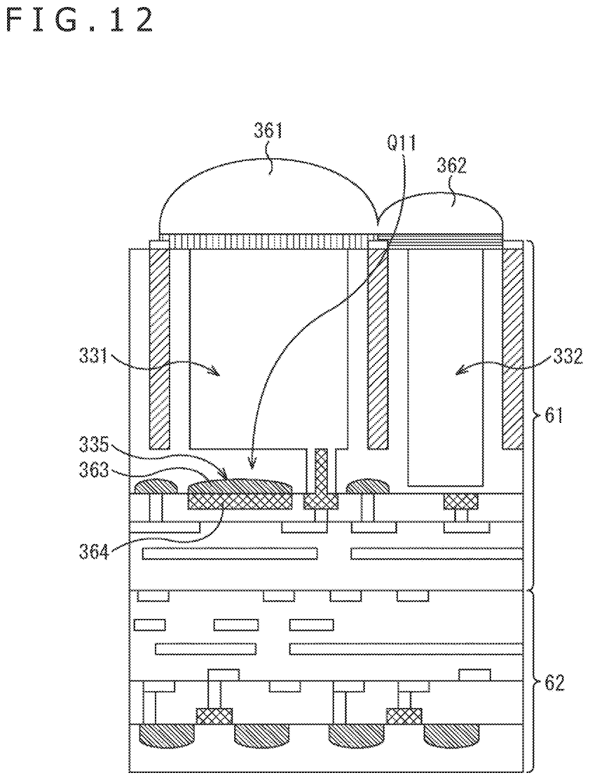

In addition, a section of the unit pixel 321 is as illustrated in FIG. 12, for example.

In the present example, on a surface of the first substrate 61 which surface is on an opposite side of the second substrate 62 side, an on-chip lens 361 and an on-chip lens 362 that condense external light and make the light incident on the photoelectric conversion portion 331 and the photoelectric conversion portion 332 are provided for the photoelectric conversion portion 331 and the photoelectric conversion portion 332.

Specifically, a part directly under the on-chip lens 361 in the first substrate 61 is the photoelectric conversion portion 331, and the photoelectric conversion portion 331 photoelectrically converts the light incident from the on-chip lens 361. In addition, a part directly under the on-chip lens 362 in the first substrate 61 is the photoelectric conversion portion 332, and the photoelectric conversion portion 332 photoelectrically converts the light incident from the on-chip lens 362.

In particular, the lens diameter of the on-chip lens 361 is larger than the lens diameter of the on-chip lens 362. Thus, because of the structure, more light is incident on the large-area pixel than on the small-area pixel. In addition, the photoelectric conversion portion 331 and the photoelectric conversion portion 332 are separated from each other by an insulator or the like.

In the unit pixel 321, the photoelectric conversion portion 331 and the photoelectric conversion portion 332 are formed on a deep side of the first substrate 61 (Si substrate), that is, on a side provided with the on-chip lens 361 and the on-chip lens 362.

Then, the charge storage capacitance 335 and a pixel transistor group of the transfer transistor 102 and the like are arranged on an opposite side of the side provided with the on-chip lens 361 and the like, so as to be stacked on a layer in which the photoelectric conversion portion 331 and the photoelectric conversion portion 332 are formed in the first substrate 61. That is, the charge storage capacitance 335 and at least some of the pixel transistors are formed in another different layer stacked on the layer in which the photoelectric conversion portion 331 is formed in the first substrate 61.

For example, the charge storage capacitance 335 is formed in a region directly below the photoelectric conversion portion 331 in the first substrate 61, and the charge storage capacitance 335 includes a diffusion layer 363 and a charge storage layer 364 including polysilicon, the diffusion layer 363 and the charge storage layer 364 being arranged so as to face each other.

In the present example, rather than having the storage layer provided within Si of the first substrate 61, the charge storage capacitance 335 has the charge storage layer 364 on a polysilicon electrode side on the first substrate 61 (Si substrate), that is, on a side connected to the transfer transistor 333 and the switching transistor 334.

Further, a dense P-type impurity (P-type impurity) is injected into a part indicated by an arrow Q11 in the first substrate 61, that is, a boundary part between the stacked layers of the photoelectric conversion portion 331 and the charge storage capacitance 335. The photoelectric conversion portion 331 and the charge storage capacitance 335 are thereby electrically separated from each other.

By thus providing the charge storage capacitance 335 directly below the photoelectric conversion portion 331, it is possible to make the regions of the photoelectric conversion portion 331 and the photoelectric conversion portion 332 wider (maximize the regions) than in a planar layout arrangement. It is thereby possible to increase an amount of charge of the photoelectric conversion portion 332 which charge can be stored in the charge storage capacitance 335 more than an area ratio between the photoelectric conversion portion 331 and the photoelectric conversion portion 332, and thus expand the dynamic range of an image obtained by the CMOS image sensor 11.

### Fifth Embodiment

### <Example of Circuit Configuration of Unit Pixel>

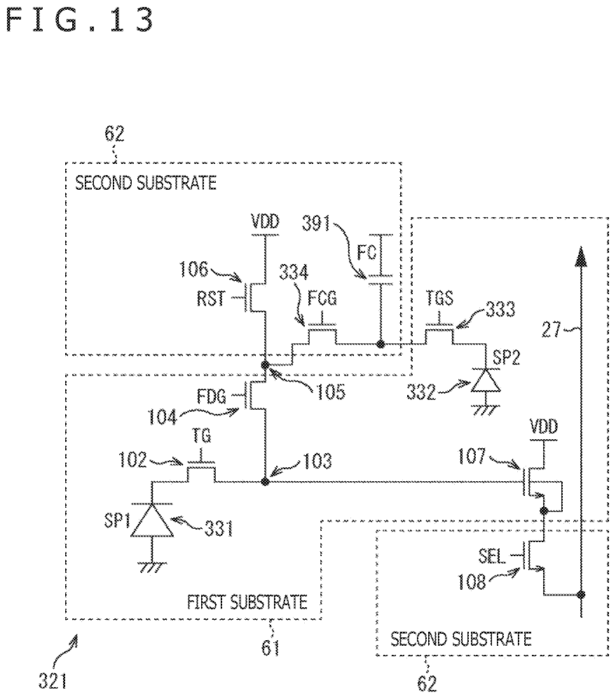

In addition, as illustrated in FIG. 13, for example, the charge storage capacitance may be provided in the second substrate 62. Incidentally, in FIG. 13, parts corresponding to those in the case of FIG. 10 are identified by the same reference signs, and description thereof will be omitted as appropriate.

In an example illustrated in FIG. 13, a unit pixel 321 includes a photoelectric conversion portion 331, a transfer transistor 102, an FD portion 103, a switching transistor 104, an FD portion 105, a reset transistor 106, a photoelectric conversion portion 332, a transfer transistor 333, a switching transistor 334, a charge storage capacitance 391, an amplifier transistor 107, and a selecting transistor 108.

A configuration of the unit pixel 321 illustrated in FIG. 13 is different from that of the unit pixel 321 in FIG. 10 in that the charge storage capacitance 391 is provided in place of the charge storage capacitance 335. Otherwise, the configuration of the unit pixel 321 illustrated in FIG. 13 is the same as that of the unit pixel 321 in FIG. 10.

In the example of FIG. 13, the charge storage capacitance 391 that functions as an intra-pixel capacitance is provided in the second substrate 62 and between the transfer transistor 333 and the switching transistor 334. The charge storage capacitance 391 retains a charge transferred from the photoelectric conversion portion 332 via the transfer transistor 333.

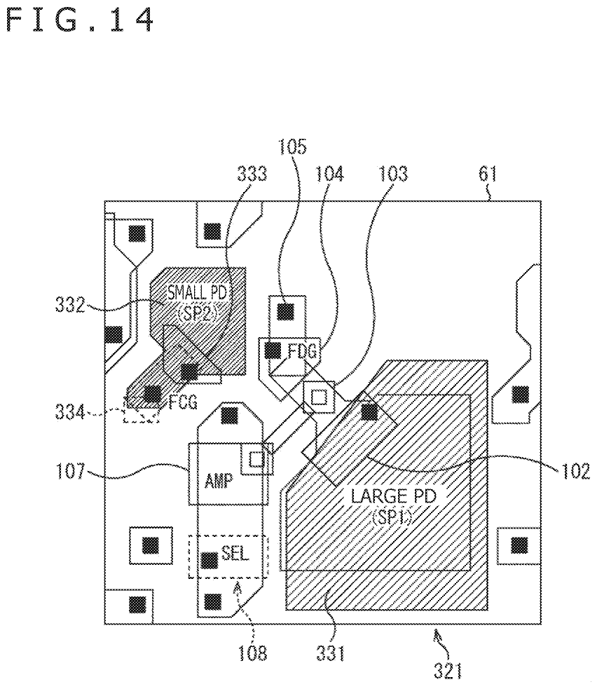

In addition, FIG. 14 illustrates a view (top view) of the part of the first substrate 61 of the unit pixel 321 illustrated in FIG. 13 as viewed from a direction perpendicular to the surface of the first substrate 61.

In the present example, the photoelectric conversion portion 331, the transfer transistor 102, the FD portion 103, the switching transistor 104, the photoelectric conversion portion 332, the transfer transistor 333, and the amplifier transistor 107 are arranged on the first substrate 61.

In particular, as viewed from the direction perpendicular to the surface of the first substrate 61, the area of the photoelectric conversion portion 331 is larger than the area of the photoelectric conversion portion 332. In addition, it is understood that the charge storage capacitance 391 is not provided in the first substrate 61 in the present example.

The charge storage capacitance 391, for example, includes an MIM (Metal-Insulator-Metal) capacitance or the like. In the present example, the charge storage capacitance 391 is provided in the second substrate 62.

When the charge storage capacitance 391 is disposed in the second substrate 62, the kind of insulating film forming (constituting) the charge storage capacitance 391 can be any kind of insulating film, and the capacitance value of the charge storage capacitance 391 can be raised easily.

In addition, the regions of the photoelectric conversion portion 331 and the photoelectric conversion portion 332 can be made wider by disposing the charge storage capacitance 391 in the second substrate 62. It is thereby possible to improve the SN characteristic by enhancing the sensitivity of the photoelectric conversion portion 331 and the photoelectric conversion portion 332, and thus obtain an image of an even higher quality.

It is to be noted that while in the foregoing, description has been made regarding an example in which the charge storage capacitance 391 is an MIM capacitance (3D MIM capacitance), the charge storage capacitance 391 is not limited to the 3D MIM capacitance, but may be anything such as a Concave MIM capacitance, a Cylinder MIM capacitance, or a Stack MIM capacitance.

With the miniaturization of the unit pixel 321, for example, the charge storage capacitance 391 having a small area and a high capacitance has been desired. Accordingly, in order to increase capacitance, for example, capacitances having various kinds of structures such as a Concave structure of a high-aspect-ratio projection type, a Cylinder structure, and a simple Stack structure, that is, a Concave MIM capacitance, a Cylinder MIM capacitance, and a Stack MIM capacitance may be used as the charge storage capacitance 391.

The charge storage capacitance 391 including such a 3D MIM capacitance, a Concave MIM capacitance, a Cylinder MIM capacitance, a Stack MIM capacitance, or the like is, for example, formed in a wiring layer of the second substrate 62. However, the charge storage capacitance 391 can be formed in a wiring layer of the first substrate 61. The wiring layer of the first substrate 61 is a layer formed so as to be stacked on a layer in which the photoelectric conversion portion 331 is formed.

### <Examples of Application to Electronic Apparatuses>

It is to be noted that the present technology is not limited to application to the solid-state imaging apparatus. That is, the present technology is applicable to electronic apparatuses in general that use a solid-state imaging apparatus in an image capturing unit (photoelectric conversion unit), the electronic apparatuses being an imaging apparatus such as a digital still camera or a video camera, a portable terminal device having an imaging function, a copying machine using a solid-state imaging apparatus in an image reading unit, and the like. The solid-state imaging apparatus may be in a form formed as one chip, or the solid-state imaging apparatus may be in a modular form having an imaging function in which form an imaging unit and a signal processing unit or an optical system are collectively packaged.

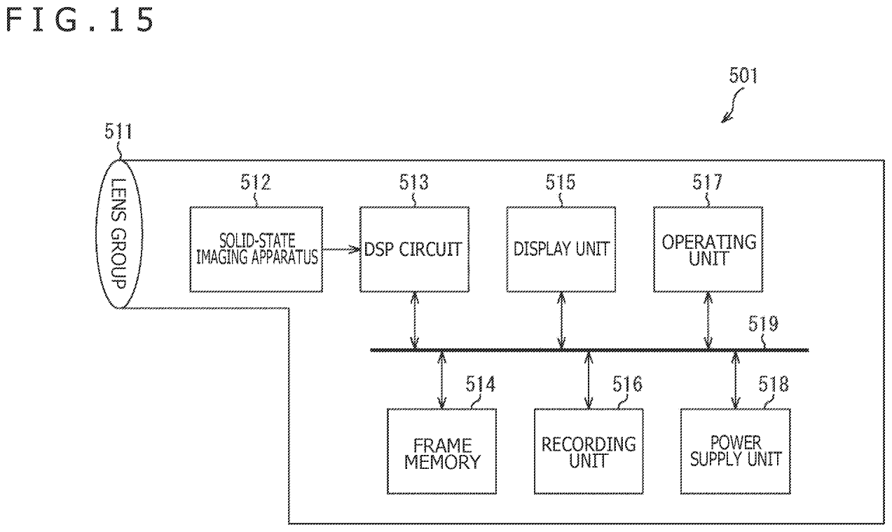

FIG. 15 is a block diagram illustrating an example of a configuration of an imaging apparatus as an electronic apparatus to which the present technology is applied.

The imaging apparatus 501 in FIG. 15 includes an optical unit 511 including a lens group and the like, a solid-state imaging apparatus (imaging device) 512 in which the configuration of the CMOS image sensor 11 in FIG. 1 is adopted, and a DSP (Digital Signal Processor) circuit 513 as a camera signal processing circuit.

In addition, the imaging apparatus 501 also includes a frame memory 514, a display unit 515, a recording unit 516, an operating unit 517, and a power supply unit 518. The DSP circuit 513, the frame memory 514, the display unit 515, the recording unit 516, the operating unit 517, and the power supply unit 518 are interconnected via a bus line 519.

The optical unit 511 captures incident light (image light) from a subject and forms an image on an imaging surface of the solid-state imaging apparatus 512. The solid-state imaging apparatus 512 converts a light amount of the incident light whose image is formed on the imaging surface by the optical unit 511 into an electric signal in pixel units, and outputs the electric signal as a pixel signal.

The display unit 515 includes, for example, a thin display such as an LCD (Liquid Crystal Display) or an organic EL (Electro Luminescence) display. The display unit 515 displays a moving image or a still image imaged by the solid-state imaging apparatus 512. The recording unit 516 records the moving image or the still image imaged by the solid-state imaging apparatus 512 on a recording medium such as a hard disk or a semiconductor memory.

The operating unit 517 issues operation commands for various functions possessed by the imaging apparatus 501 under the operation of a user. The power supply unit 518 supplies various kinds of power as operating power for the DSP circuit 513, the frame memory 514, the display unit 515, the recording unit 516, and the operating unit 517 to these supply targets as appropriate.

### <Examples of Usage of Image Sensor>

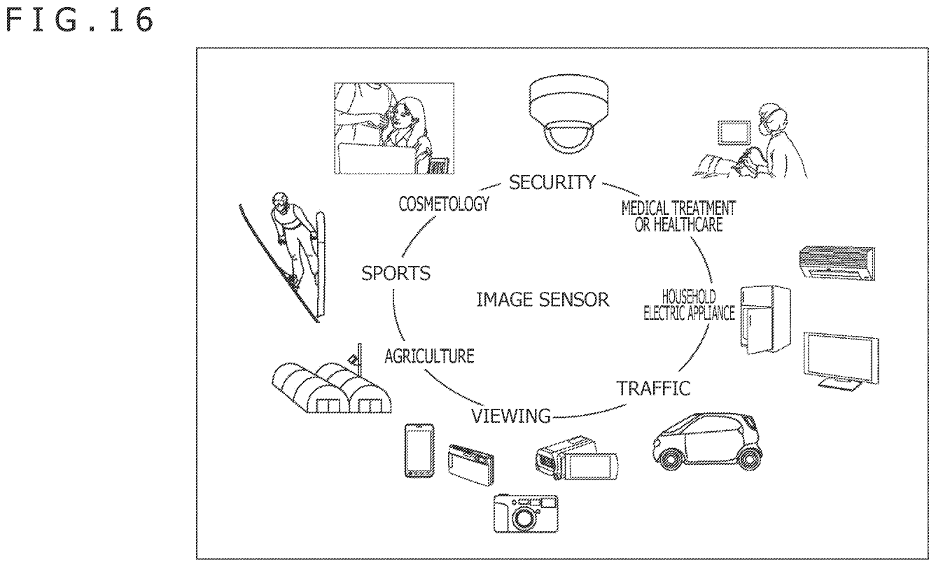

FIG. 16 is a diagram illustrating examples of usage of the CMOS image sensor 11 described above.

The CMOS image sensor 11 described above can, for example, be used in various cases of sensing light such as visible light, infrared light, ultraviolet light, and X-rays as follows.
A device that photographs an image provided for viewing, the device being a digital camera, a portable apparatus having a camera function, or the like
A device provided for traffic for safe driving such as an automatic stop, recognition of the state of a driver, or the like, the device being vehicle-mounted sensors for photographing the front, rear, surroundings, inside, and the like of an automobile, a surveillance camera for monitoring traveling vehicles and a road, a distance measuring sensor for measuring a distance between vehicles or the like, and the like
A device provided for a household electric appliance such as a TV set, a refrigerator, or an air conditioner in order to photograph a gesture of a user and perform an apparatus operation according to the gesture
A device provided for medical treatment or healthcare, the device being an endoscope, a device for performing angiography by receiving infrared light, or the like
A device provided for security, the device being a surveillance camera for the purpose of crime prevention, a camera for the purpose of personal authentication, or the like
A device provided for cosmetology, the device being a skin measuring instrument for photographing a skin, a microscope for photographing a scalp, or the like
A device provided for sports, the device being an action camera targeted for a sports application or the like, a wearable camera, or the like
A device provided for agriculture, the device being a camera for monitoring the state of a field or a crop or the like

### <Example of Application to Mobile Body>

Thus, the technology according to the present disclosure (present technology) can be applied to a variety of products. For example, the technology according to the present disclosure may be implemented as a device mounted in one of kinds of mobile bodies such as an automobile, an electric vehicle, a hybrid electric vehicle, a motorcycle, a bicycle, a personal mobility vehicle, an airplane, a drone, a vessel, and a robot.

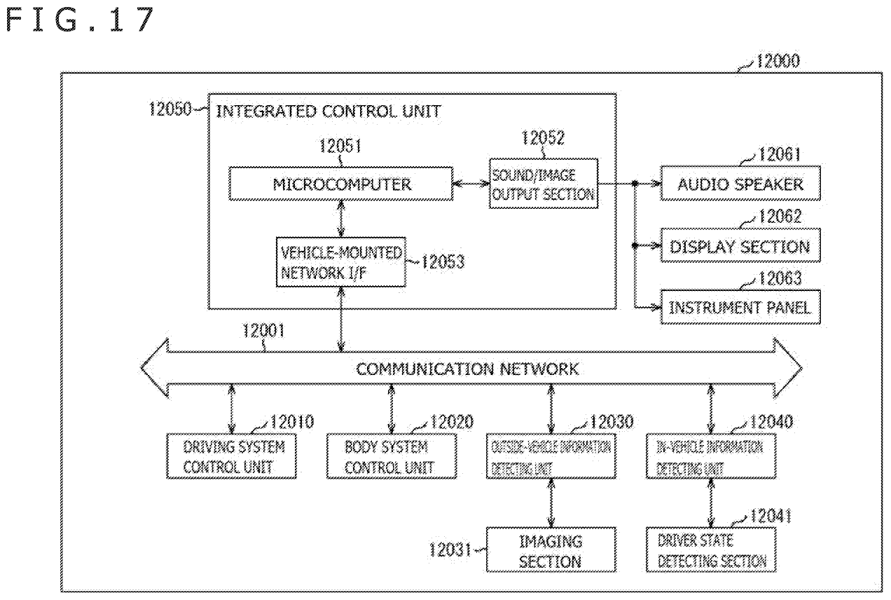

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

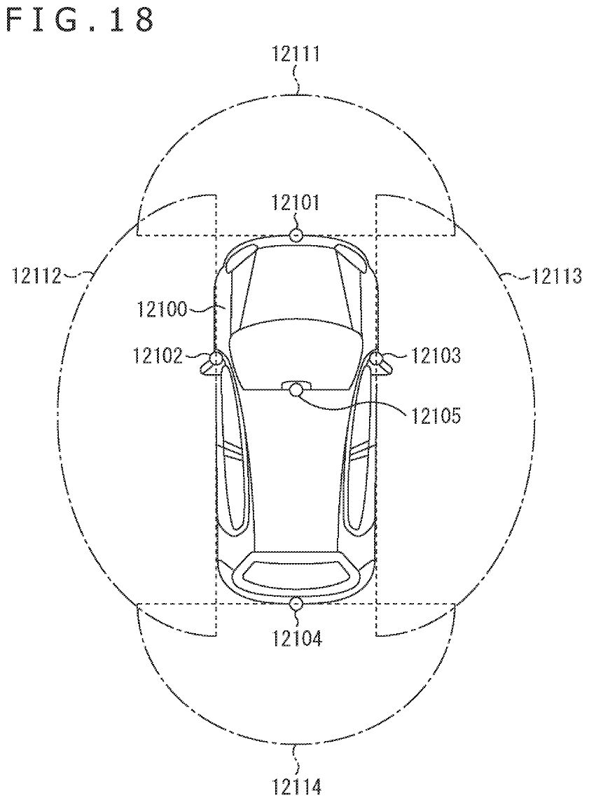

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described above. The technology according to the present disclosure can be applied to the imaging section 12031 or the like in the configuration described above. Specifically, the CMOS image sensor 11 illustrated in FIG. 1, for example, can be used as the imaging section 12031. This can thereby improve the SN characteristic and consequently obtain an image of higher quality.

It is to be noted that the present technology is not limited to application to a solid-state imaging apparatus that detects a distribution of incident light amounts of visible light and images the distribution as an image, and is applicable to a solid-state imaging apparatus that images, as an image, a distribution of incident amounts of infrared rays, X-rays, particles, or the like, or in a broad sense, to solid-state imaging apparatuses (physical quantity distribution detecting apparatuses) in general such as a fingerprint detecting sensor that detects a distribution of another physical quantity such as pressure or capacitance, and images the distribution as an image.

In addition, the present technology is not limited to the solid-state imaging apparatuses and is applicable to semiconductor apparatuses in general that have a different semiconductor integrated circuit.

Embodiments of the present technology are not limited to the embodiments described above and are susceptible of various changes without departing from the spirit of the present technology.

For example, it is possible to adopt modes in which all or a part of the multiple embodiments described above are combined with each other.

In addition, effects described in the present specification are illustrative only and are not limited, and there may be effects other than those described in the present specification.

Further, the present technology can also adopt the following configurations.

(1)

A solid-state imaging apparatus including:
a pixel array unit including multiple unit pixels,
the unit pixels each including a photoelectric conversion portion, an FD portion configured to retain a charge transferred from the photoelectric conversion portion, and multiple pixel transistors for driving the unit pixel,
the photoelectric conversion portion, the FD portion, and a corresponding one of the multiple pixel transistors that is directly connected to the FD portion being provided in the same substrate, and
at least one of the multiple pixel transistors that is not directly connected to the FD portion being provided in another substrate different from the substrate.
   (2)

The solid-state imaging apparatus according to (1), in which
an amplifier transistor that is among the multiple pixel transistors and that is configured to output a signal corresponding to the charge retained in the FD portion is provided in the substrate.
   (3)

The solid-state imaging apparatus according to (2), further including:
a separating portion configured to electrically separate a well in which the photoelectric conversion portion is formed and a well in which the amplifier transistor is formed in the substrate from each other.
   (4)

The solid-state imaging apparatus according to (3), in which
the separating portion is formed by an insulator.
   (5)

The solid-state imaging apparatus according to (3) or (4), in which
at least a part of the separating portion is a through DTI that penetrates the substrate.
   (6)

The solid-state imaging apparatus according to any one of (3) to (5), in which
at least a part of the separating portion is a front DTI that does not penetrate the substrate.
   (7)

The solid-state imaging apparatus according to any one of (1) to (6), in which
a switching transistor that is among the multiple pixel transistors and that is used for connecting the FD portion and another FD portion to each other is provided in the substrate.
   (8)

The solid-state imaging apparatus according to any one of (1) to (7), further including:
an intra-pixel capacitance configured to retain a charge obtained in the unit pixel.
   (9)

The solid-state imaging apparatus according to (8), in which
the intra-pixel capacitance is provided in the substrate.
   (10)

The solid-state imaging apparatus according to (8), in which
the intra-pixel capacitance is provided in the other substrate different from the substrate.
   (11)

The solid-state imaging apparatus according to any one of (8) to (10), in which
the unit pixel further includes another photoelectric conversion portion smaller than the photoelectric conversion portion, and
the other photoelectric conversion portion is provided in the substrate.
   (12)

The solid-state imaging apparatus according to (11), in which
the intra-pixel capacitance retains the charge transferred from the other photoelectric conversion portion.
   (13)

The solid-state imaging apparatus according to any one of (8) to (12), in which
the intra-pixel capacitance is provided in another layer stacked on a layer in which the photoelectric conversion portion is formed.
   (14)

The solid-state imaging apparatus according to any one of (8) to (13), in which
the intra-pixel capacitance is a 3D MIM capacitance.
   (15)

The solid-state imaging apparatus according to any one of (8) to (13), in which
the intra-pixel capacitance is a Concave MIM capacitance.
   (16)

The solid-state imaging apparatus according to any one of (8) to (13), in which
the intra-pixel capacitance is a Cylinder MIM capacitance.
   (17)

An electronic apparatus including:
a solid-state imaging apparatus including a pixel array unit including multiple unit pixels,
the unit pixels each including a photoelectric conversion portion, an FD portion configured to retain a charge transferred from the photoelectric conversion portion, and multiple pixel transistors for driving the unit pixel,
the photoelectric conversion portion, the FD portion, and a corresponding one of the multiple pixel transistors that is directly connected to the FD portion being provided in the same substrate, and
at least one of the multiple pixel transistors that is not directly connected to the FD portion being provided in another substrate different from the substrate.

### REFERENCE SIGNS LIST

11: CMOS image sensor
21: Pixel array unit
22: Vertical driving unit
23: Column processing unit
28: Signal processing unit
91: Unit pixel
101: Photoelectric conversion portion
102: Transfer transistor
103: FD portion
104: Switching transistor
105: FD portion
106: Reset transistor
107: Amplifier transistor
108: Selecting transistor
131: Through DTI
201: Front DTI
321: Unit pixel
331: Photoelectric conversion portion
332: Photoelectric conversion portion
335: Charge storage capacitance
391: Charge storage capacitance

1. A solid-state imaging apparatus comprising:
a pixel array unit including multiple unit pixels,
the unit pixels each including a photoelectric conversion portion, an FD portion configured to retain a charge transferred from the photoelectric conversion portion, and multiple pixel transistors for driving the unit pixel,
the photoelectric conversion portion, the FD portion, and a corresponding one of the multiple pixel transistors that is directly connected to the FD portion being provided in the same substrate, and
at least one of the multiple pixel transistors that is not directly connected to the FD portion being provided in another substrate different from the substrate.

2. The solid-state imaging apparatus according to claim 1,
wherein an amplifier transistor that is among the multiple pixel transistors and that is configured to output a signal corresponding to the charge retained in the FD portion is provided in the substrate.

3. The solid-state imaging apparatus according to claim 2, further comprising:
a separating portion configured to electrically separate a well in which the photoelectric conversion portion is formed and a well in which the amplifier transistor is formed in the substrate from each other.

4. The solid-state imaging apparatus according to claim 3, wherein
the separating portion is formed by an insulator.

5. The solid-state imaging apparatus according to claim 3, wherein
at least a part of the separating portion is a through DTI that penetrates the substrate.

6. The solid-state imaging apparatus according to claim 3, wherein
at least a part of the separating portion is a front DTI that does not penetrate the substrate.

7. The solid-state imaging apparatus according to claim 1, wherein
a switching transistor that is among the multiple pixel transistors and that is used for connecting the FD portion and another FD portion to each other is provided in the substrate.

8. The solid-state imaging apparatus according to claim 1, further comprising:
an intra-pixel capacitance configured to retain a charge obtained in the unit pixel.

9. The solid-state imaging apparatus according to claim 8, wherein
the intra-pixel capacitance is provided in the substrate.

10. The solid-state imaging apparatus according to claim 8, wherein
the intra-pixel capacitance is provided in the other substrate different from the substrate.

11. The solid-state imaging apparatus according to claim 8, wherein
the unit pixel further includes another photoelectric conversion portion smaller than the photoelectric conversion portion, and
the other photoelectric conversion portion is provided in the substrate.

12. The solid-state imaging apparatus according to claim 11, wherein
the intra-pixel capacitance retains the charge transferred from the other photoelectric conversion portion.

13. The solid-state imaging apparatus according to claim 8, wherein
the intra-pixel capacitance is provided in another layer stacked on a layer in which the photoelectric conversion portion is formed.

14. The solid-state imaging apparatus according to claim 8, wherein
the intra-pixel capacitance is a 3D MIM capacitance.

15. The solid-state imaging apparatus according to claim 8, wherein
the intra-pixel capacitance is a Concave MIM capacitance.

16. The solid-state imaging apparatus according to claim 8, wherein
the intra-pixel capacitance is a Cylinder MIM capacitance.

17. An electronic apparatus comprising:
a solid-state imaging apparatus including a pixel array unit including multiple unit pixels,
the unit pixels each including a photoelectric conversion portion, an FD portion configured to retain a charge transferred from the photoelectric conversion portion, and multiple pixel transistors for driving the unit pixel,
the photoelectric conversion portion, the FD portion, and a corresponding one of the multiple pixel transistors that is directly connected to the FD portion being provided in the same substrate, and
at least one of the multiple pixel transistors that is not directly connected to the FD portion being provided in another substrate different from the substrate.
